(19) United States
(12) Patent Application Publication
(10) Pub. No.: US 2017/0123674 A1
(43) Pub. Date: May 4, 2017

(54) STORAGE SYSTEM THAT INCLUDES A PLURALITY OF ROUTING CIRCUITS AND A PLURALITY OF NODE MODULES CONNECTED THERETO

(71) Applicant: KABUSHIKI KAISHA TOSHIBA, Tokyo (JP)

(72) Inventors: Yuko MORI, Yokohama Kanagawa (JP); Atsuhiro KINOSHITA, Kamakura Kanagawa (JP)

(21) Appl. No.: 15/135,299

(22) Filed: Apr. 21, 2016

Related U.S. Application Data
(60) Provisional application No. 62/250,158, filed on Nov. 3, 2015.

(51) Int. Cl. G06F 3/06; G06F 12/02; G11C 16/10

(52) U.S. Cl. CPC G06F 3/0607; G11C 16/10; G06F 12/0246; G06F 3/0688; G06F 3/0659; G06F 3/0635; G06F 2212/7201

(57) ABSTRACT

A storage device includes a storage unit and connection units. The storage unit has routing circuits electrically networked with each other, each of the routing circuits being locally connected to a plurality of node modules, each of the node modules including a nonvolatile memory device and is configured to count a number of times write operations have been carried out with respect thereto and output the counted number. Each of the connection units is connected to one or more of the routing circuits, and configured to access each of the node modules through one or more of the routing circuits, in accordance with access requests from a client, and maintains, in each entry of a table, a key address of data written thereby and attributes of the data, the attributes including the number of times corresponding to a nonvolatile memory device into which the data have been written.

### CROSS-REFERENCE TO RELATED APPLICATIONS

This application is based upon and claims the benefit of priority from U.S. Provisional Patent Application No. 62/250,158, filed on Nov. 3, 2015, the entire contents of which are incorporated herein by reference.

### FIELD

Embodiments described herein relate generally to a storage system, in particular, a storage system that includes a plurality of routing circuits and a plurality of node modules connected thereto.

### BACKGROUND

A storage device conventionally may not be able to determine characteristics of data stored therein, such as importance, etc., of the data. To determine the characteristics of the data stored in the data storage device, a process to determine the characteristics of the data may conventionally need to be carried out using software.

### BRIEF DESCRIPTION OF THE DRAWINGS

FIG. 1 illustrates a configuration of a storage system according to a first embodiment.

FIG. 2 illustrates a configuration of a connection unit included in the storage system.

FIG. 3 illustrates a conversion table stored in the connection unit according to the first embodiment.

FIG. 4 illustrates an array of a plurality of field-programmable gate arrays (FPGA), each of which includes a plurality of node modules.

FIG. 5 illustrates a configuration of the FPGA.

FIG. 6 illustrates a configuration of the node module.

FIG. 7 illustrates a structure of a packet.

FIG. 8 is a flow chart illustrating an operation of the node module in the storage system according to the first embodiment.

FIG. 9 is a flow chart illustrating an operation of the connection unit in the storage system according to the first embodiment.

FIG. 10 is a flow chart illustrating a data process based on the number of write times according to the first embodiment.

FIG. 11 illustrates an enclosure in which the storage system is accommodated.

FIG. 12 is a plan view of the enclosure from Y direction according to the coordinates in FIG. 11.

FIG. 13 illustrates an interior of the enclosure viewed from the Z direction according to the coordinates in FIG. 11.

FIG. 14 illustrates a backplane of the enclosure.

FIG. 15 illustrates a use example of the storage system.

FIG. 16 is a block diagram illustrating a configuration of an NM card.

FIG. 17 is a flow chart of a data process based on the number of write times according to the first embodiment.

FIG. 18 illustrates a process of changing key information according to the first embodiment.

FIG. 19 is a flow chart illustrating a different process of detecting the correlation in a storage system according to the first embodiment.

FIG. 20 illustrates a configuration of a node module according to a second embodiment.

FIG. 21 schematically illustrates a relationship between a block and a write unit.

FIG. 22 illustrates a structure of a write count table according to the second embodiment.

FIG. 23 is a flow chart illustrating an operation of the node module in the storage system according to the second embodiment.

FIG. 24 schematically illustrates a region of the storage system in which metadata are stored in the node module according to a third embodiment.

FIG. 25 is a flow chart illustrating a process of writing metadata in the storage system according to the third embodiment.

FIG. 26 schematically illustrates an example of a region of the storage system in which lock information is stored in the node module according to a fourth embodiment.

FIG. 27 is a flow chart illustrating a process of writing the lock information in the storage system according to the fourth embodiment.

FIG. 28 illustrates a storage system according to a first variation.

FIG. 29 illustrates connection of a client with a storage system according to a second variation.

FIG. 30 illustrates connection of a client and a data processing device with a storage system according to a third variation.

### DETAILED DESCRIPTION

A storage system according to an embodiment includes a storage unit and a plurality of connection units. The storage unit has a plurality of routing circuits electrically networked with each other, each of the routing circuits being locally connected to a plurality of node modules, each of the node modules including a nonvolatile memory device and is configured to count a number of times write operations have been carried out with respect thereto and output the counted number. Each of the connection units is connected to one or more of the routing circuits, and configured to access each of the node modules through one or more of the routing circuits, in accordance with access requests from a client, and maintains, in each entry of a table, a key address of data written thereby and attributes of the data, the attributes including the number of times corresponding to a nonvolatile memory device into which the data have been written.

A storage system according to one or more embodiments is described below with reference to the drawings.

### First Embodiment

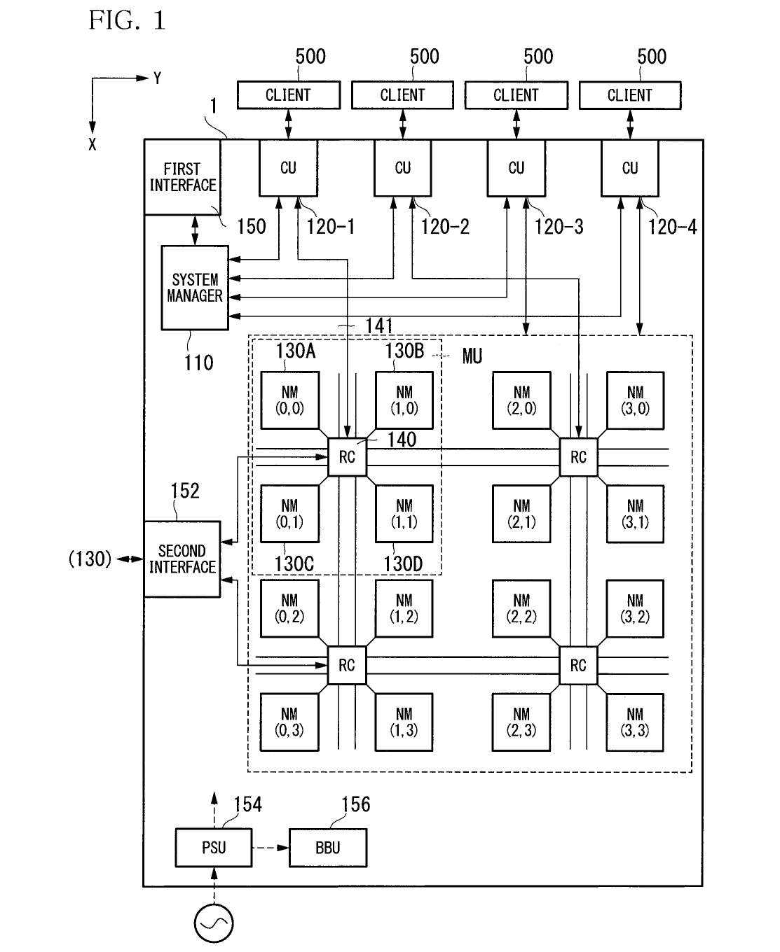

FIG. 1 illustrates a configuration of a storage system 1 according to a first embodiment. The storage system 1 may include a system manager 110, a plurality of connection units (CU) 120-1 to 120-4, one or more memory units MU, each including a plurality of node modules (NM) 130 and a routing circuit (RU) 140, a first interface 150, a second interface 152, a power supply unit (PSU) 154, and a battery backup unit (BBU) 156. The configuration of the storage system 1 is not limited thereto. When no distinction is made among the connection units, a mere expression of a connection unit 120 is used. While the number of connection units is four in FIG. 1, the storage system 1 may include an arbitrary number of connection units, where the arbitrary number is at least two.

Each of clients 500 is a device which is external to the storage system 1, and may be an information processing device used by a user of the storage system 1, or a device which transmits various commands to the storage system 1 based on commands, etc., which are received from a different device. Moreover, each of the clients 500 may be a device which generates various commands to transmit a generated result to the storage system 1 based on results of information processing in the interior thereof. Each of the client 500 transmits, to the storage system 1, a read command which instructs reading of data, a write command which instructs writing of data, a delete command which instructs deletion of data, etc., to the storage system 1. A command is in a form of a packet which includes information representing the type of a request, data to be a subject of the request, or information which specifies the subject of the request. The type of the request includes reading, writing, or deletion of data. The data to be the subject of the request include data which are written in accordance with a write request. Information which specifies the subject of the request includes key information on data which are read in accordance with a read request, or key information on data which are deleted in accordance with a delete request.

The system manager 110 manages the storage system 1. The system manager 110, for example, executes processes such as recording of a status of the connection unit 120, resetting, power supply management, failure management, temperature control, address management including management of an IP address of the connection unit 10.

The system manager 110 is connected to an administrator terminal (not shown), which is one of the external devices, via the first interface 150. The administrator terminal is a terminal device which is used by an administrator which manages the storage system 1. The administrator terminal provides an interface such as a graphical user interface (GUI), etc., to the administrator, and transmits instructions for the storage system 1 to the system manager 110.

The connection unit (write controller) 120 is a connection element (a connection device, a command receiver, a command receiving apparatus, a response element, a response device), which has a connector connectable with one or more clients 500. The connection unit 120, upon receiving a command transmitted from a client 500, uses a communication network of node modules to transmit packets (described below) including information which indicates the nature of a process designated by the received command to a node module 130 having an address (physical address) corresponding to key information included in the command from the client 500.

The connection unit 120 transmits a write request to the node module 130 which corresponds to key information designated by the write command to cause data to be written. The connection unit 120 acquires data stored in association with key information designated by the read command and transmits the acquired data to the client 500.

The client 500 transmits a request designating the key information to the connection unit 120. The key information in the request is converted to a physical address of a node module 130 and delivered to a first NM memory 132 within the node module 130. There is no limitation about the location of the conversion, so that the conversion may be performed at an arbitrary location, including the system manager 110.

The client 500 transmits a command specifying the key information to the storage system 1, and the connection unit 120 executes a process which corresponds to the command based on a physical address corresponding to the key information in the present embodiment. Alternatively, the client 500 may transmit a command which specifies a series of logical addresses such as the LBA, etc., to the storage system 1, and the connection unit 120 may execute a process corresponding to the command based on a physical address corresponding to the series of logical addresses. Here, it is assumed that the conversion of the key information to the physical address is carried out by the connection unit 120.

A plurality of memory units MU is connected to each other via a communication network. Each of the memory units MU includes four node modules 130A, 130B, 130C, 130D, and one RC 140. A mere expression of “node module 130” is used when no distinction is made among the node modules hereinafter. Each of the memory units MU transmits data to a destination memory unit MU and a node module 130 therein via the communication network, which connects the memory units MU (memory modules, a memory including communications functions, a communications device with a memory, a memory communications device). While each of the memory units MU includes the four node modules 130 and the one RC 140 according to the present embodiment, the configuration of the memory unit MU is not limited thereto. For example, the memory unit MU may include one node module 130, and a node controller of the node module 130 may receive a request transmitted by a connection unit 120 and performs a process based on the received request and transmit data.

The node module 130 includes a non-volatile memory and stores data requested from the client 500. Each of the memory units MU includes a routing circuit (RC, a torus routing circuit) 140, and the plurality of RCs is arranged in a matrix configuration. The matrix configuration is an arrangement in which elements thereof are lined up in a first direction and a second direction which intersects the first direction.

The torus routing circuit is a circuit in which the plurality of node modules 130 is connected in a torus form as described below. When the node modules 130 are connected in the torus form, layers of the open systems interconnection (OSI) reference model that are lower than those when the torus connection form is not adopted can be used for the RC 140.

Each of the RCs 140 transfers packets transmitted from the connection unit 120, the other RCs 140, etc., through a mesh-shaped network. The mesh-shaped network is a network which is configured in a mesh shape or a lattice shape, or, in other words, a network in which each of the RCs 140 is located at an intersection of one of vertical lines and one of horizontal lines that intersect the vertical lines. Each of the RCs 140 is connected to two or more RC interfaces 141. The RC 140 is electrically connected to the neighboring RC 140 via the RC interface 141.

The system manager 110 is electrically connected to the connection units 120 and a predetermined number of RCs 140.

The node module 130 is electrically connected to the neighboring node module 130 via the RC 140 and the below-described packet management unit (PMU) 170.

FIG. 1 shows an example of a rectangular network in which the node modules 130 are arranged at lattice points. Here, coordinates of the lattice points are described with coordinates (x, y) which are expressed in decimal notation. Thus, the position information of each node module 130 arranged at a lattice point is described with a relative node address (x_{D}, y_{D}) (in decimal notation) that correspond to the coordinates of the lattice point. Moreover, in FIG. 1, a node module 130 which is located at the upper-left corner has a node address of the origin (0, 0). The relative node address of the other node modules 130 increases/decreases with varying of integer value in the horizontal direction (X direction) and the vertical direction (Y direction).

Each node module 130 is connected to the other node modules 130 adjacent in two or more different directions. For example, the upper left node module 130 (0, 0) is connected to the node module 130 (1, 0), which neighbors in the X direction via the RC 140; the node module 130 (0, 1), which neighbors in the Y direction, and the node module 130 (1, 1), which neighbors in the slant direction.

While the node modules 130 in FIG. 1 are arranged at the lattice points of the rectangular lattice, the arrangement of the node modules 130 is not limited thereto. The shape of the lattice may be such that the node modules 130 arranged at the lattice points may be connected to the node modules 130 which neighbor in two or more different directions, and may be a triangle, a hexagon, etc., for example. Moreover, while the node modules 130 are arranged in a two-dimensional plane in FIG. 1, the node modules 130 may be arranged in three-dimensional space. When the node modules 130 are arranged in the three-dimensional space, the locations of the node modules 130 may be specified with three values of (x, y, z). Moreover, when the node modules 130 are arranged in the two-dimensional plane, those node modules 130 located on opposite ends may be connected together so as to form the torus shape.

The torus shape is a type of connections in which the node modules 130 are circularly connected, and there are at least two paths to connect two node modules 130, including a first path extending in a first direction and a second path extending in a second direction that is opposite to the first direction.

In FIG. 1, each of the connection units 120 is connected to different one of the RCs 140 on a one-to-one basis. When the connection unit 120 accesses a node module 130 in response to a request from the client 500, the connection unit 120 generates a packet which the RC 140 can transfer and execute and transmits the generated packets to the RC 140 which is connected thereto. Each connection unit 120 may be connected to a plurality of RCs 140, and each the RCs 140 may be connected to a plurality of connection units 120.

The first interface 150 electrically connects the system manager 110 and the administrative terminal.

The second interface 152 electrically connects the RCs 140 and RCs of a different storage system. Such a connection causes the node modules included in the plurality of storage systems to be logically coupled, allowing use as one storage device. The second interface 152 is electrically connected to one or more RC 140s via the RC interface 141. In FIG. 1, the two RC interfaces 141, each of which is connected to the corresponding RC 140, are connected to the second interface 152.

The PSU 154 converts an external power source voltage provided from an external power source into a predetermined direct current (DC) voltage and provides the converted DC voltage to the elements of the storage system 1. The external power source may be an alternating current (AC) power source such as 100 V, 200 V, etc., for example.

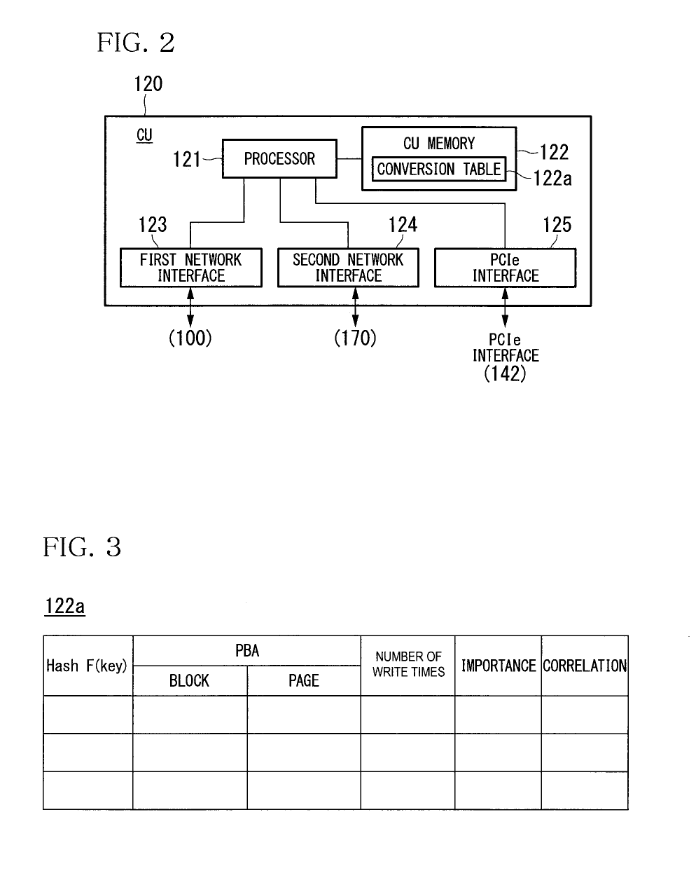

The BBU 156 has a secondary cell, and stores power supplied from the PSU 154. When the storage system 1 is electrically isolated from the external power source, the BBU 156 provides an auxiliary power source voltage to the elements of the storage system 1. A node controller (NC) 131 (See FIG. 2) of the node module 130 performs a backup of data, using the auxiliary power source voltage. The entire data in the first NM memory 132 are subject to the backup by the node controller 131.

(Connection Unit) FIG. 2 illustrates a configuration of the connection unit 120. The connection unit 120 may include a processor 121, such as a CPU, a CU memory 122, a first network interface 123, a second network interface 124, and a PCIe interface 125. The configuration of the connection unit 120 is not limited thereto. The processor 121 executes application programs while using the CU memory 122 as a working area to perform various processes. The first network interface 123 is an interface for connection to the client 500. The second network interface 124 is an interface for connection to the system manager 110. While the CU memory 122 may be a RAM, for example, it is not limited thereto, and various types of memories may be used. The PCIe interface 125 is an interface for connection to the RC 140.

The processor 121 specifies a memory unit MU including a non-volatile memory (first NM memory 132) to be accessed based on information (key information) included in a command (a write command or a read command) transmitted by the client 500. In other words, the write controller specifies a targeted one of the plurality of memory units MU, based on information associated with a write command, and transmits a write request for writing data to the receiver (1310) in the memory unit MU specified as the destination, via the communication network. More, the processor 121 converts the key information included in the command received from the client 500 using a predetermined hash function into an address which is fixed-data-length information. The address converted from the key information using the predetermined hash function is called as a key address hereinafter. The processor 121 acquires a physical address stored in a conversion table 122a in association with the key address and transmits a command including the physical address to the PCIe interface 125. In this way, the processor 121 transmits a request (a write request or a read request) via the communication network of memory units MU to the target memory unit MU specified based on the key information.

Moreover, the processor 121 receives the number of write times of each node module 130 via the PCIe interface 125 from each node module 130 and performs data processes (data processor, control device for storage system) based on the number of write times. For example, the processor 121 performs a process of determining whether or not the importance of data is greater or equal to a predetermined criteria or a process of determining whether or not correlation among data sets is equal to or greater than a predetermined criteria. The processor 121 updates the conversion table 122a based on the number of write times and results of the data processes based on the number of write times.

The conversion table 122a in the CU memory 122 stores a physical address (PBA), the number of write times, importance information, and correlation information in association with each key address. FIG. 3 illustrates a structure of the conversion table 122a according to the first embodiment. The number of write times is the number of times data (a value) corresponding to the key address have been written and is increased in accordance with a receipt, from the client 500, of a write command including the key information corresponding to the key address.

The importance information and the correlation information include information indicating the characteristics of the data that is assumed based on the number of write times. The importance information and the correlation information are updated by the processor 121 based on the number of write times of writes.

The importance information indicates that the importance of data is equal to or greater than the predetermined criteria. The predetermined criteria may be any criteria that enable to determine whether or not the data are important for the process of the client 500 and, for example, is a threshold (first threshold) of the number of write times. As described below, data of which number of write times is higher than the first threshold are determined to be important. Important data may include database information for which update is frequently carried out.

The correlation information indicates that correlation among a plurality of data sets stored in the storage system 1 is equal to or greater than the predetermined criteria. The predetermined criteria for the correlation may be any criteria that enable to determine whether or not the data are important and, for example, is a threshold (second threshold) of a difference in the numbers of write times. As described below, a plurality of data sets (third data and fourth data) of which difference in the numbers of write times is equal to or greater than the threshold is determined to be highly correlated. The correlated data may include video data, and voice data which is updated at the same time as the video data.

(FPGA)

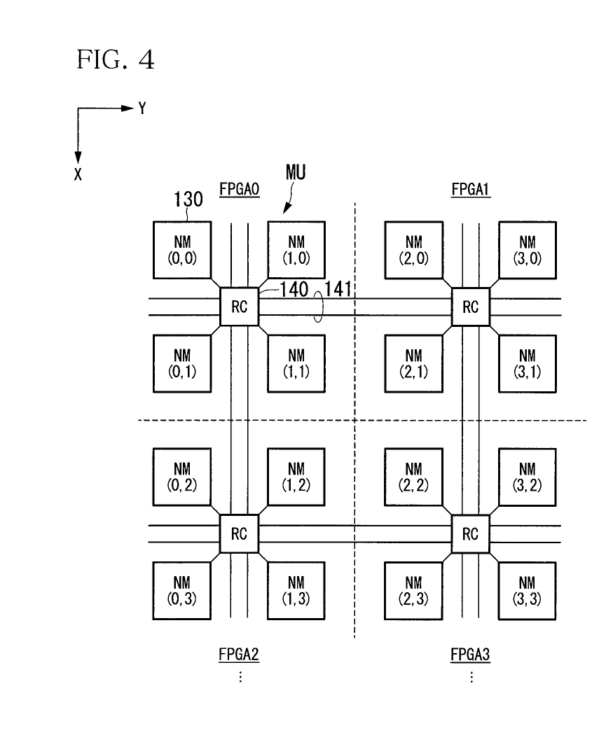

FIG. 4 illustrates a configuration of an array of a plurality of field-programmable gate arrays (FPGA), each of which includes a plurality of node modules 130. While the storage system 1 may include the plurality of FPGAs, each including the one RC 140 and the four node modules 130, the configuration of the storage system 1 may not be limited thereto. In FIG. 4, the storage system 1 includes four FPGAs 0-3. For example, the FPGA 0 includes one RC 140 and four node modules (0, 0), (0, 1), (1, 0), and (1, 1).

FPGA addresses of the four FPGAs 0-3 are respectively denoted by decimal notations as (000, 000), (010, 000), (000, 010), and (010, 010), for example.

The one RC 140 and the four node modules of each FPGA are electrically connected via the RC interface 141 and the below-described packet management unit 160. The RC 140 performs routing of packets in a data transfer operation, based on the FPGA address (x, y).

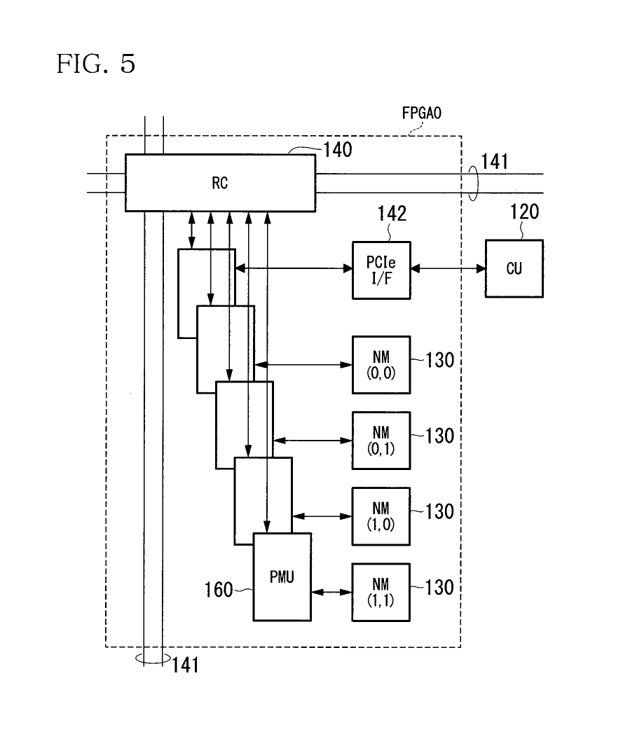

FIG. 5 illustrates a configuration of the FPGA. The configuration shown in FIG. 5 is common to the FPGAs 0-3. The FPGA in FIG. 5 include one RC 140, four node modules 130, five packet management units 160, and a PCIe interface 142, but the configuration of the FPGA is not limited thereto.

Four packet management units 160 are provided in correspondence with the four node modules 130, and one packet management unit 160 is provided in correspondence with the PCIe interface 142. Each of the packet management units 160 analyses packets transmitted by the connection unit 120 and/or the RC 140. Each of the packet management units 160 determines whether or not coordinates (relative node address) included in the packets and the own coordinates (relative node address) match. If the coordinates described in the packets and the own coordinates match, the packet management unit 160 transmits the packets directly to the node module 130 connected thereto. On the other hand, if the coordinates described in the packets and the own coordinates do not match (when they are different coordinates), the packet management unit 160 returns information indicating non-match of the coordinates to the RC 140.

For example, when the node address of the final destination position is (3, 3), the packet management unit 160, which is connected to the node address (3, 3), determines that the coordinate (3, 3), which is described in the analyzed packets, and the own coordinate (3, 3) match. Therefore, the packet management unit 160 connected to the node address (3, 3) transmits the analyzed packets to the node module 130 of the node address (3, 3) that is connected thereto. The transmitted packets are analyzed by a node controller 131 (below described) thereof. In this way, the FPGA cause a process in response to a request described in a packet to be performed, such as storing data into the non-volatile memory within the node module 130.

The PCIe interface 142 transmits requests or packets, etc., from the connection unit 120 to the packet management unit 160. The packet management unit 160 analyses the requests or the packets, etc. The packets transmitted to the packet management unit 160 corresponding to the PCIe interface 142 are further transferred to the different node module 130 via the RC 140.

(Node Module)

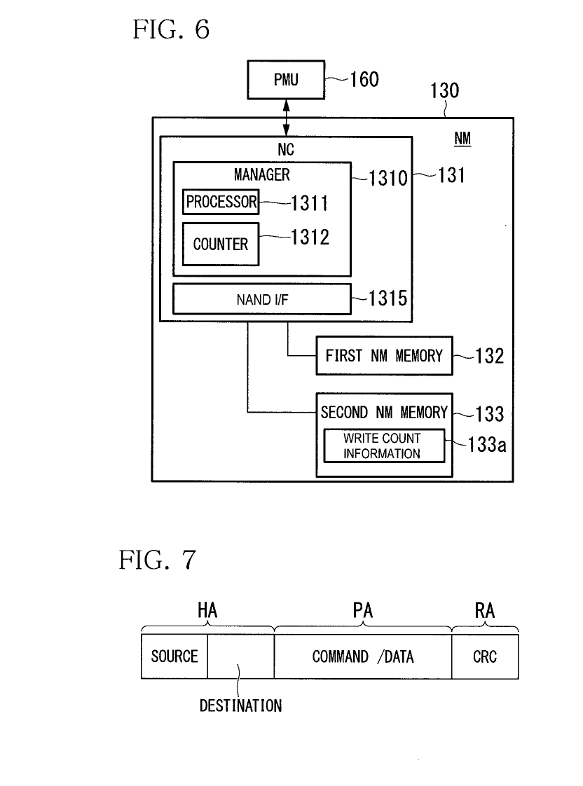

Below a node module according to the present embodiment is described. FIG. 6 illustrates a configuration of the node module 150.

The node module 130 includes the node controller (NC) 131, the first node module (NM) memory 132, which functions as a (main) memory, a second NM memory 133, which the node controller 131 uses as a working memory. The configuration of the node module 130 is not limited thereto.

The node controller 131 is, for example, embedded multi-media card (eMMC®). The corresponding packet management unit 160 is electrically connected to the node controller 131. While the node controller 131 may include a manager 1310 and an NAND interface 1315, the configuration of the node controller 131 is not limited thereto. The manager 1310 is a data management device and a packet processing device which are embedded into the node controller 131.

The manager 1310 performs the below-described process as a packet processing device. The manager 1310 includes a receiver which receives a packet (including the write request) via the packet management unit 160 from the connection unit 120 or the other node modules 130; and a transmitter which transmits a packet via the packet management unit 160 to the connection unit 120 or the other node module 130. When the destination of the packet is the own node module 130, the manager 1310 executes a process corresponding to the packet (a request recorded in the packet). For example, when the request is an access request (a read request or a write request), the manager 1310 executes an access to the first NM memory 132. In accordance with control of the manager 1310, the NAND interface 1315 executes access to the first NM memory 132 and the second NM memory 133. “Executing access” includes erasure of data stored in the first NM memory 132 and the second NM memory 133; writing of data into the first NM memory 132 and the second NM memory 133, and reading of the data written into the first NM memory 132 and the second NM memory 133. When the destination of the received packet is not the node module 130 corresponding thereto, the manager 1310 transfers the packet to the other RC 140.

While the manager 1310 may include a processor 1311 which performs a data management process and a counter 1312, the configuration of the manager 1310 is not limited thereto. The processor 1311 performs garbage collection, refresh, wear leveling, etc., as a data management process.

The garbage collection is a process carried out to reuse a region of a physical block in which unwanted (or invalid) data are stored. During the garbage collection, the processor 1311 moves data (valid data) other than the unwanted data from a physical block to an arbitrary physical block and remaps the originating physical block. Unwanted data are data to which no address is associated, and valid data are data to which an address is associated.

The refresh is a process of rewriting data stored in a target physical block into a different physical block. During the refresh, the processor 1311, for example, executes a process of writing the whole data stored in the target physical block or data (valid data) other than unwanted data in the target physical block into a different physical block.

The wear leveling is a process of controlling such that the number of write times, the number of erase times, or the elapsed time from erasure becomes uniform among the physical blocks or among the memory elements. The processor 1311 may execute the wear leveling through a process of selecting a write destination when a write request is received, or through a data rearrangement process independently of the write request.

The counter 1312 counts the number of times data have been written by the processor 1311. According to the first embodiment, the processor 1311 increments the number of write times in the counter 1312 each time the process of writing data is executed on the first NM memory 132. The number of write times with respect to the first NM memory 132 that was counted by the counter 1312 is written into the second NM memory 133 as write count information 133a. The write count information 133a is transmitted to the connection unit 120 by the node controller 131 (the transmitter thereof). In other words, the transmitter transmits data representing the number of write times counted by the counter 1312.

In the present embodiment the number of write times in the counter 1312 is incremented each time a write operation into the first NM memory 132 is executed, but the manner of counting the number is not limited thereto. The number of write times may be incremented only for data writing based on a write request.

The first NM memory 132 is a non-volatile memory of a NAND flash memory, for example. For the second NM memory 133, various RAMs such as a DRAM (dynamic random access memory), etc., are used. When the first NM memory 132 provides the function as a working memory, the second NM memory 132 does not have to be disposed in the node module 130.

As described above, according to the present embodiment, the plurality of RCs 140 is connected by the RC interface 142, and each of the RCs 140 and the corresponding node modules 130 are connected via the PMUs 160, which forms a communication network of the node modules 130. Alternatively, the plurality of NMs 150 may be directly connected to each other, not via the RC 140, to form the communication network.

(Interface Standards)

Interface standards in the storage system 1 according to the embodiments are described below. According to the present embodiment, interfaces which electrically connect the above-described elements may employ the following standards:

The RC interface 141 which connects the RCs 140 may employ low voltage differential signaling (LVDS) standards, etc.

The RC interface 141 which electrically connects the RC 140 and the connection unit 120 may employ PCI Express (PCIe) standards, etc.

The RC interface 141 which electrically connects the RC 140 and the second interface 152 may employ the LVDS standards, and joint test action group (JTAG) standards, etc.

The RC interface 141 which electrically connects the node module 130 and the system manager 110 may employ the PCIe standards and inter-integrated circuit (I2C) standards. Moreover, the interface standards of the node module 130 may be the eMMC® standards.

These interface standards are one example, so that other interface standards can be employed as required.

(Packet)

FIG. 7 illustrates a data structure of a packet. The packet to be transmitted in the storage system 1 according to the present embodiment includes a header area HA; a payload area PA; and a redundancy area RA.

The header area HA includes addresses (from_x, from_y) in the X and Y directions of a transmission source, addresses (to_x, to_y) in the X and Y directions of a transmission destination.

The payload area PA includes a request, data, etc., for example. The data size of the payload area PA is variable.

The redundancy area RA includes CRC (cyclic redundancy check) codes, for example. The CRC codes are codes (information) used for detecting errors in data in the payload area PA.

The RC 140, upon receiving the packet of the above-described configuration, determines a routing destination based on a predetermined transfer algorithm. Based on the transfer algorithm, the packet is transferred between the RC 140s to reach the node module 130 having the node address of a final destination.

(Operations)

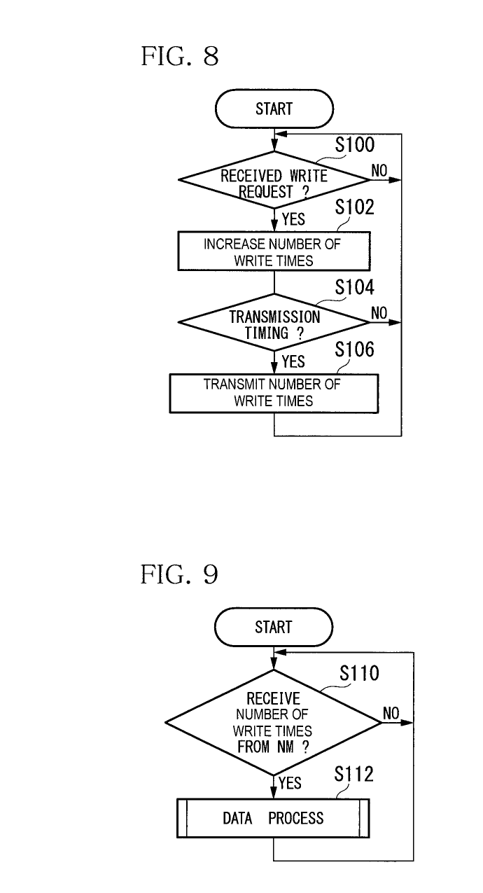

Various operations in the storage system according to the first embodiment are described below. FIG. 8 is a flow chart illustrating an operation of the node module 130 in the storage system 1 according to the first embodiment. The node controller 131 determines or not whether a write request has been received (S100). If a write request is not receives (No in S100), the node controller 131 is on stand-by until a write request is received. If a write request is received (Yes in S100), the node controller 131 increments the number of write times f writes in the counter 1312 and updates the write count information 133a stored in the second NM memory 133 (S102). The processor 1311 of node module 130 writes data into a physical address included in the write request of the first NM memory 132 in accordance with the write request. In other word, the processor 1311 (writer) writes the data into the non-volatile memory when the receiver 1310 receives the write request.

In the present embodiment, the node controller 131 increments the number of write times when the write request is received, but the manner to increment the number is not limited thereto. For example, the node controller 131 may increase the number of write times when the NAND interface 1315 writes data into the first NM memory 132 based on the write request, or when an write error does not occur as a result of a verification carried out after the data writing by the first NM memory 132. Moreover, the node controller 131 may increase the number of write times when information indicating completion of the data writing based on the write request has been transmitted to the client 500 upon completion of the data writing.

The processor 1311 determines whether or not the timing of transmitting the write count information 133a to the connection unit 120 has come (S104). For example, the processor 1311 determines that the transmission timing has come when a repeat period to transmit the write count information 133a has come. If the write count information 133a exceeds a predetermined threshold, the processor 1311 may determine that the transmission timing of the write count information 133a has come. If the transmission timing has not come (No in S104), the process returns S100. If the transmission timing has come (Yes in S104), the processor 1311 causes the NAND interface 1315 to read the write count information 133a stored in the second NM memory 133 and transmit the read result to the connection unit 120 (S106). In this way, the number of write times by the counter 1312 is received by the PCIe interface 125 (receiver) and output to the connection unit 120 (write controller).

FIG. 9 is a flow chart illustrating an operation of the connection unit 120 in the storage system 1 according to the first embodiment. The processor 121 of the connection unit 120 determines whether or not the write count information 133a was received from the node module 130 via the PCIe interface 125 by the processor 121 (S110). Based on the received write count information 133a, the processor 121 executes a data process (S112).

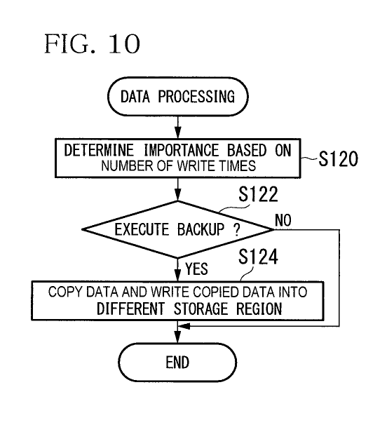

FIG. 10 is a flow chart illustrating a data process based on the number of write times according to the first embodiment. The processor 121 of the connection unit 120 updates the number of write times that corresponds to the key address in the conversion table 122a in response to a receipt of the write count information 133a transmitted by the node module 130. The processor 121 extracts, from a packet including the write count information 133a, an address of a node module 130 (source node module) that has transmitted the packet. The processor 121 sets the number of write times indicated by the write count information 133a to an entry of the conversion table 122a corresponding to a key address, which corresponds to the address extracted. The processor 121 (data processor) determines whether or not the importance of the data stored in the node module 130 is greater than or equal to the predetermined criteria based on the number of write times in the conversion table 122a (S120). In general, data can be considered to be important if the number of read times of the data is large. When data are read from NAND flash memory, rewriting of the data is required because the data stored in the NAND flash memory tend to be damaged because of a “read disturb.” Therefore, it can be said that the number of write times reflects the importance of the data. The processor 121, for example, determines that the importance of the data stored in the physical address is equal to or greater than the predetermined criteria when the number of write times in the conversion table 122a is greater than the first threshold and determines that the importance of the data stored in the physical address is less than the predetermined criteria when the number of write times of writes is equal to or less than the first threshold.

In the present embodiment, the processor 121 determines that the importance of the data is greater than the predetermined criteria when the number of write times is equal to or greater than the first threshold, but the manner to determine the importance of the data is not limited thereto. The processor 121, for example, may determine a predetermined set of data that are ranked higher based on the number of write times as the data that have the importance greater than the predetermined criteria.

The processor 121 determines whether or not backup of the data is executed (S122). If it is determined that the importance is equal to or greater than the criteria, the processor 121 determines to perform the backup. During the backup, the processor 121 controls such that data with the greater importance are copied to the first NM memory 132 of the other node module 130 (S124). Then, the processor 121 transmits, to the node module 130 which stores the data of which importance is equal to or greater than the criteria, a read request designating the physical address thereof, receives the data, and transmits a write command which specifies a physical address of a backup destination and the received data. For the backup, the node controller 131 targets the part of the data that were determined to have the importance which is equal to or greater than the criteria among data in the first NM memory 132 that are accessible from the node controller 131.

When a plurality of node modules 130 is accommodated in a distributed manner in a plurality of storage devices, in other words, the plurality of memory units MU is physically separated from each other, the processor 121 causes the copied data to be written into a node module 130 accommodated in a different storage device. In other words, the processor 121 specifies a storage region which is physically distant from the node module 130 that stores the original data as a backup destination of the copied data. The physically-distant storage region is a storage region which extends over a unit in which reading is prohibited. For example, the physically-distant storage region is a storage region which is arranged in a different rack, a storage region which is arranged in a different enclosure, or a storage region arranged in a different card. As described above, the processor 121 backs up data to a non-volatile memory of a memory unit MU different from the memory unit MU from which the data are copied.

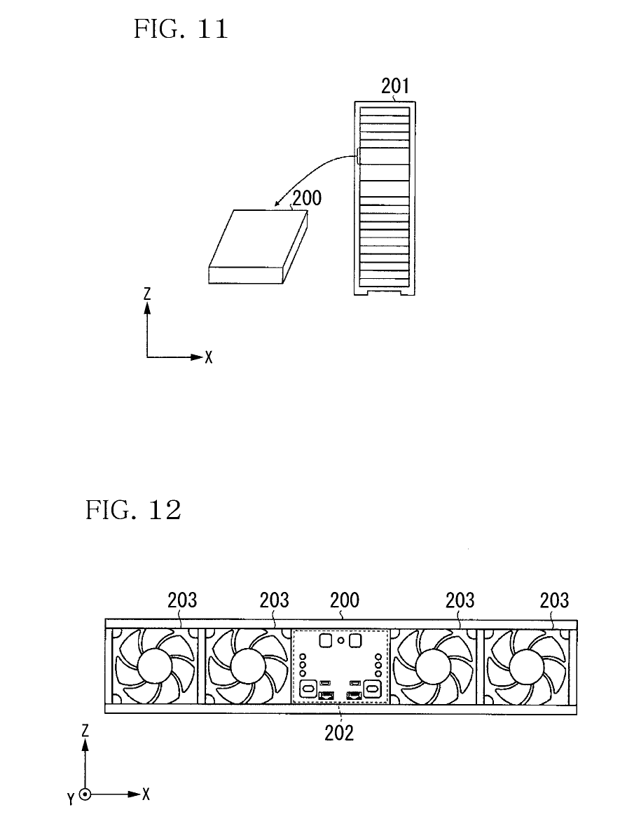

FIG. 11 illustrates an enclosure in which the storage system 1 is accommodated. The storage system 1 is accommodated in an enclosure 200 which can be mounted in a server rack 201.

FIG. 12 is a plan view of the enclosure 200 from Y direction according to the coordinates in FIG. 11. A console panel 202 on which a power button, various LEDs, and various connectors are arranged is provided at the center of the enclosure 200 that is viewed from Y direction. Two fans 203 which inhales or exhales the air are provided on each side of the console panel 202 in X direction.

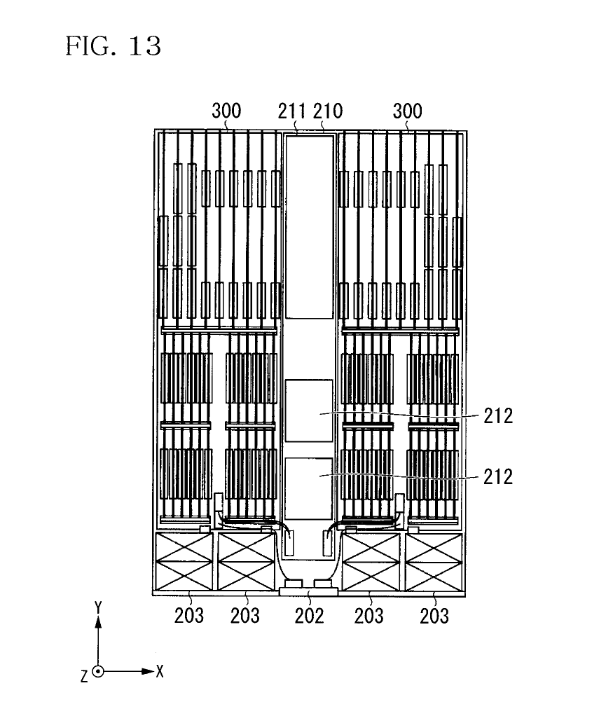

FIG. 13 illustrates an interior of the enclosure 200 viewed from Z direction according to the coordinates in FIG. 11. A backplane 210 for the power supply is accommodated in the center portion of the enclosure 200. Then, a backplane 300 is accommodated on each of left and right sides of the backplane 210 for the power supply. The connection units 120, the node modules 130, the first interface 150, and the second interface 152 that are mounted on a card substrate are attached to each of the backplanes 300 to function as one storage system 1. In other words, two storage systems 1 can be accommodated in the enclosure 200. The enclosure 200 can operate even when only one backplane 300 is accommodated therein. Moreover, when two backplanes 300 are accommodated therein, the node modules 130 included in the two storage systems 1 can be mutually connect via a connector (not shown) provided on an end in Y direction, and the integrated node modules 130 in the two storage systems 1 can server as one storage region.

In the power supply backplane 210, two power supply devices 211 are stacked in Z direction (height) of the enclosure 200 and disposed at an end of the enclosure 200 in Y direction (back face side of the enclosure 200). Also, two batteries 212 are lined up along Y direction at the face (front face) side of the enclosure 200 in Y direction (depth direction). The two power supply device 211 generates internal power based on commercial power supplied via a power supply connector (not shown) and supplies the generated internal power to the two backplanes 300 via the power supply backplane 210. The two batteries 212 are backup power source which generate internal power when there is no supply of the commercial power, such as a power outage.

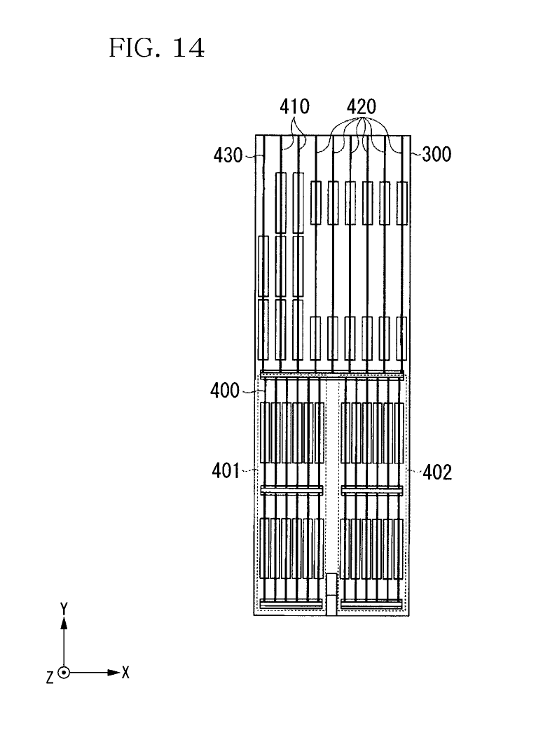

FIG. 14 illustrates the backplane 300. Each of the system manager 110, the connection units 120, the node modules 130, the first interface 150, and the second interface 152 is mounted on one of card substrates 400, 410, 420, and 430. Each of the card substrates 400, 310, 420, and 430 is attached to a slot provided in the backplane 300. The card substrate on which the node modules 130 are mounted is denoted as an NM card 400. The card substrate on which the first interface 150 and the second interface 152 are mounted is denoted as an interface card 410. The card substrate on which the connection unit 120 is mounted is denoted as a CU card 420. The card substrate on which the system manager 110 is mounted is denoted as an MM card 430.

One MM card 430, two interface cards 410, and six CU cards 420 are attached to the backplane 300 such that they are arranged in X direction and extend in Y direction. Moreover, twenty-four NM cards 400 are attached to the backplane 300 such that they are arranged along two rows in Y direction. The twenty-four NM cards 400 are categorized into a block (first block 401) including twelve NM cards 400 on side in −X-direction side and a block (second block 402) including twelve NM cards on the side in +X-direction. This categorization is based on the attachment position.

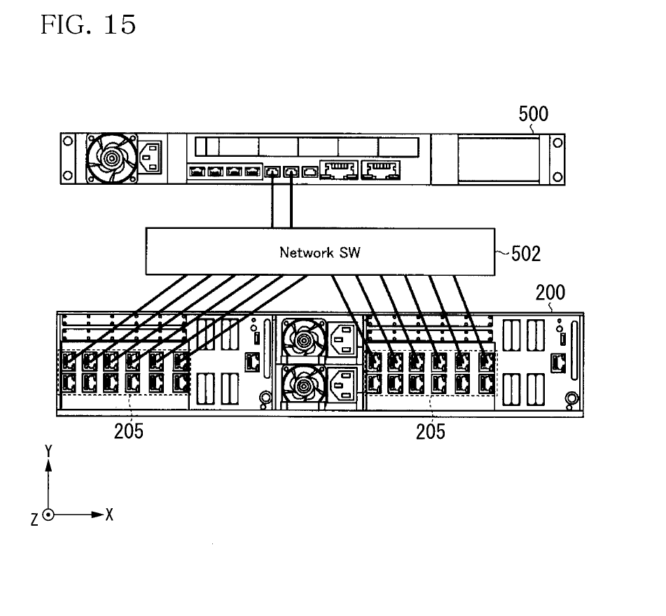

FIG. 15 illustrates a use example of the enclosure 200 including the storage system 100. The client 500 is connected via a network switch (Network SW) 502 and a plurality of connectors 205 to the enclosure 200. The storage system 1 accommodated in the enclosure 200 may interpret a request received from the client 500 in the CU card 420 and access the node module 130. In the CU card 420, a server application such as a key value database, etc., is executed, for example. The client 500 transmits a request which is compatible with the server application. Here, each of the connectors 205 may be connected to arbitrary one of the CU cards 420.

As illustrated in FIGS. 11-15, the enclosure 200 is physical distant from the other enclosures 200, and each of the enclosure may be independently suffer a defect or an error. The connection unit 120 causes the data copied from an NM card 400 of an enclosure 200 to be stored in another NM card 400 in another enclosure 200, which is physically distant from the enclosure 200 from which the data are copied, to back up the data. Similarly, the connection unit 120 may causes the data copied from an NM card 400 of an enclosure 200 to be stored in another NM card 400 in another enclosure 200 in another rack 201, to back up the data.

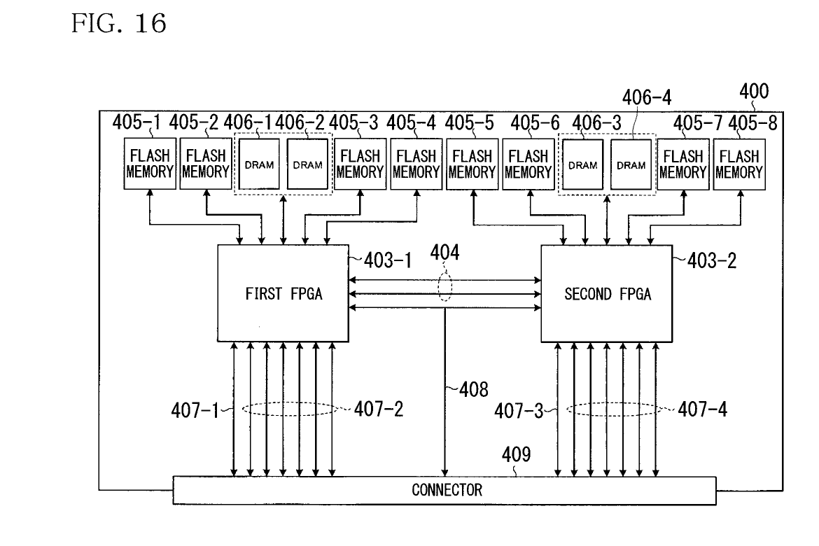

FIG. 16 is a block diagram illustrating a configuration of the NM card 400. In FIG. 16, X direction is arbitrary. In FIG. 16, the NM card 400 includes a first FPGA 403-1, a second FPGA 403-2, flash memories 405-1 to 405-4, DRAMs 406-1 and 406-2, flash memories 405-5 to 405-8, DRAMs 406-3 and 406-4, and a connector 409. The configuration of the NM card 400 is not limited thereto. The first FPGA 403-1, the flash memories 405-1 and 405-2, the DRAMs 406-1 and 406-2, and the flash memories 405-3 and 405-4 and the second FPGA 403-2 and the flash memories 405-1 and 405-2, the DRAMs 406-3 and 406-4, and the flash memories 405-7 and 405-8 are positioned symmetrically with respect to a center line of the NM card 400 extending in the vertical direction in FIG. 16. The connector 409 is a connection mechanism which is physically and electrically connected to a slot on the backplane 300. The NM card 400 may conduct communications with the interface card 410, the CU card 420, and the MM card 430 via wirings in the connector 409 and the backplane 300.

The first FPGA 403-1 is connected to the four flash memories 405-1 to 405-4 and the two DRAMs 406-1 and 406-2. The first FPGA 403-1 includes therein the four node controllers 131. The four node controllers 131 included in the first FPGA 403-1 use the DRAMs 406-1 and 406-2 as the second NM memory 133. Moreover, the four node controllers 131 included in the first FPGA 403-1 use respectively different one of the flash memories 405-1 to 405-4 as the first NM memory 132. In other words, the first FPGA 403-1, the flash memories 405-1 to 405-4, and the DRAMs 406-1 and 406-2 correspond to one node module group (memory unit MU) including the four node modules 130.

The second FPGA 403-2 is connected to the four flash memories 405-5 to 405-8 and the two DRAMs 406-3 and 406-4. The second FPGA 403-2 includes therein the four node controllers 131. The four node controllers 131 included in the second FPGA 403-2 use the DRAMs 406-3 and 406-4 as the second NM memory 133. Moreover, the four node controllers 131 included in the second FPGA 403-2 use respectively different one of the flash memories 405-5 to 405-8 as the first NM memory 132. In other words, the second FPGA 403-2, the flash memories 405-5 to 405-8, and the DRAMs 406-3 and 406-4 correspond to a node module group (memory unit MU) including the four node modules 130.

The first FPGA 403-1 is connected to the connector 409 via one PCIe signal path 407-1 and six LVDS signal paths 407-2. Similarly, the second FPGA 403-2 is connected to the connector 409 via one PCIe signal path 407-3 and six LVDS signal paths 407-4. The first FPGA 403-1 and the second FPGA 403-2 are connected via two LVDS signal paths 404. Moreover, the first FPGA 403-1 and the second FPGA 403-2 are connected to the connector 409 via the I2C interface 408.

The NM card 400 shown in FIG. 16 may be a smallest unit in the storage system 1 that is replaceable. The connection unit 120 causes the data to be backed up and the copy of the data to be stored in different NM cards 400.

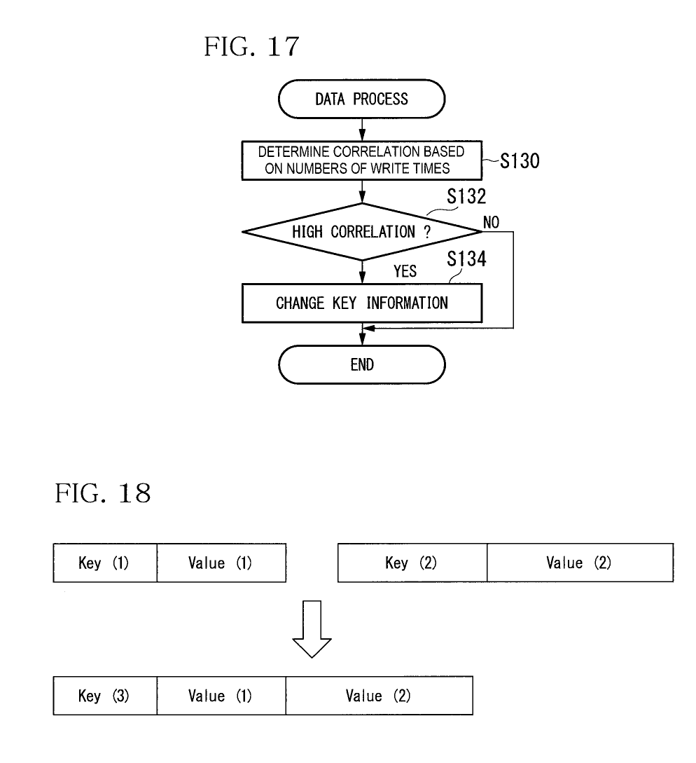

A flow of another data process according to the storage system 1 of the first embodiment is described below. FIG. 17 is a flow chart illustrating the data process based on the number of write times according to the first embodiment.

The processor 121 of the connection unit 120 updates the number of write times in an entry of the conversion table 122a that is associated with the key address corresponding to the write count information 133a received from the node module 130. The processor 121, for example, extracts an address of the packet transmission source node module 130 from the write count information 133a included in a packet from the node module 130. The processor 121 sets the number of write times indicated by the write count information 133a to the number of write times in the conversion table 122a that is associated with the corresponding key address. The processor 121 updates the number of write times corresponding to data stored in the storage system 1 based on the write count information 133a transmitted by the plurality of node modules 130 in the storage system 1. The processor 121 determines whether or not correlation among data sets stored in the node module 130 is equal to or greater than the criteria based on the number of write times in the conversion table 122a (S132).

The processor 121, for example, compares the numbers of write times in the conversion 122a and search data sets for which the difference in the number of write times is equal to or less than a second threshold. In other words, the processor 121 determines whether or not a difference in the number of write times between two non-volatile memories included in different memory units MU is equal to or less than the second threshold. If there are data sets of which difference in the number of write times is determined to be equal to or less than the second threshold, it is determined that the correlation among the plurality of data sets are equal to or greater than the criteria. (Here, it is assumed that data sets of which importance are at similar levels, the data sets are relevant.) If no such data sets are found, it is determined that no data sets of which correlation is high are stored in the storage system 1.

For the second threshold, any value that is reasonably to determine that the correlation among the data sets is high can be set. For example, for the data sets of which the write process is performed simultaneously based on write commands, it is determined by the processor 121 that the correlation is equal to or greater than the criteria, because the numbers of write times for these data sets are the same.

The processor 121 determines whether or not there are data sets of which correlation is equal to or greater than the criteria are stored in the storage system 1 (S132). When it is determined that there are data sets of which correlation is equal to or greater than the criteria (Yes in S134), the processor 121 updates key information corresponding to the data sets (S134). The processor 121 updates the key information such that the speed to access the data sets is increased.

FIG. 18 illustrates a process of changing key information according to the first embodiment. When it is determined that the correlation of data (Value (1)) and data (Value (2)) is equal to or greater than the criteria, the processor 121 changes information (key information) corresponding to the data (Value (1)) and the data (Value (2)), such that a single unit of key information is set so as to correspond to both the data (Value (1)) and the data (Value (2)). That is, the single unit of key information corresponds to a first address of a memory unit in which the data (Value (1)) are stored and a second address of a memory unit in which the data (Value (2)) are stored. As a result, if a command which includes the changed key information is received, the connection unit 120 converts the changed key information to the first address and the second address.

In other words, the processor 121 causes the key address of the data (Value (1)) and the key address of the data (Value (2)) to be the same. More specifically, the processor 121 sets a hash function and key information such that the key address of the data (Value (1)) and the key address of the data (Value (2)) are both key address (Key (3)). In this way, the processor 121 changes the key address of the data (Value (1)) from Key (1) to Key (3) and the key address of the data (Value (2)) from Key (2) to Key (3). After the processor 121 changes the key address of the data (Value (1)) and the key address of the data (Value (2)) to Key (3), the processor 121 transmits, to the client 500, information indicating that key information of the data (Value (1)) and the key information of the data (Value (2)) are key information corresponding to the key address Key (3). In this way, the processor 121 causes the client 500 to change the key information to be included in commands for accessing the data (Value (1)) and the data (Value (2)). In other words, the processor 121 sets a common key for reading and writing two sets of data which are respectively stored in the different non-volatile memories when the processor 121 determines that the difference is equal to or less than the second threshold. In this way, the connection unit 120 performs an address conversion using a function when the connection unit 120 receives the common key, and through the address conversion the common key is converted into physical addresses of the different non-volatile memories. Since the processor 121 can access (write and read) the data (Value (1)) and data (Value (2)) in response of receipt of the command containing the key address Key (3), the speed to access the data (Value (1)) and the data (Value (2)) can be increased.

The processor 121 may change key information on at least one of a plurality of data sets of which correlation is equal to or greater than the criteria and send, to a plurality of memory units MU, write requests which respectively cause first NM memories 132 therein to store the corresponding data set. In other words, the processor 121 generates the common key when the processor 121 determines that the difference is equal to or less than the second threshold. Then, the connection unit 120 operates to write the two sets of data in the different non-volatile memories.

When the plurality of data sets is written into a plurality of first NM memories 132, data writing of the plurality of data sets is executed by different node controllers 131. The processor 121, for example, changes key information such that the data (Value (1)) and the data (Value (2)) are written into different NM first memories 132 of the different node modules 130, so that the data (Value (1)) and the data (Value (2)) are separately stored. As different node modules 130 execute data writing of the data (Value (1)) and the data (Value (2)) or data reading thereof, the speed to access the data (Value (1)) and the data (Value (2)) is increased.

The processor 121 may determine whether the correlation of the plurality of data sets is greater than or equal to the criteria based on the time at which each of the plurality of data sets has been written. The processor 121 stores the time at which the write command for each data set was received in association with the key information and compares the times at which the write commands were received for data sets of which difference in the numbers of write times is equal to or greater than a threshold. When the times at which the write commands were received for the plurality of data sets are the same or close enough to find the correlation thereof, it is determined that the correlation of the plurality of data sets is equal to or greater than the criteria. In this way, the processor 121 may increase the accuracy of determining the correlation of the plurality of data sets.

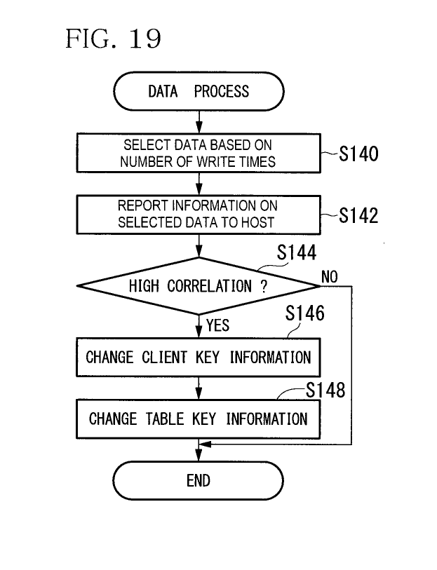

Moreover, the storage system 1 may have the client 500 to detect the correlation of the plurality of data sets. FIG. 19 is a flow chart illustrating a process of detecting the correlation carried out in the storage system 1 according to the first embodiment.

The processor 121 selects data stored in the storage system 1 based on the numbers of write times in the conversion table 122a (S140). The processor 121 selects the plurality of data sets of which difference in the numbers of write times is equal to or less than a third threshold, for example. The processor 121 reports information of the selected data sets to the client 500 (S141). Here, the processor 121 transmits key information on the selected data sets to the client 500, for example.

The client 500 determines whether the correlation of the plurality of data sets reported by the storage system 1 is equal to or greater than the criteria (S144). The client 500 determines whether the correlation of the plurality of data sets is equal to or greater than the criteria, based on an operation of the administrator of the data, for example. The client 500 completes the process if it is determined that the correlation of the plurality of data sets is less than the criteria. The client 500 changes key information corresponding to the plurality of data sets if it is determined that the correlation of the plurality of data sets is equal to or greater than the criteria (S146). As described above, the client 500 changes key information, such that the speed of accessing the plurality of data sets of which correlation is equal to or greater than the reference is increased. Moreover, the client 500 may change the key information for the plurality of data sets, such that the plurality of data sets may be accessed in a distributed manner.

The client 500 transmits the changed key information, and the data (Value) corresponding to the key information to the storage system 1. The processor 121 updates the conversion table 122a based on the data and key information received from the client 500 (S148).

As described above, the storage system 1 according to the first embodiment may include a write controller 120 which specifies a memory unit 130 including a non-volatile memory based on information included in a write command transmitted by a host (client) and transmits a write request to the memory unit; a non-volatile memory 132; a writer 1311 which writes data into the non-volatile memory based on the write request received from the write controller; and a counter 1312 which counts the number of times writing of the data is carried out by the writer to output the counted result to the write controller to detect the importance, correlation, etc., of the data based on the number of write times stored in the memory unit.

In other words, according to the storage system 1 according to the first embodiment, the number of write times into the first NM memory 132 is counted by the node module 130 for garbage collection, refresh, and wear leveling, and the number may be transmitted from the node module 130 to the connection unit 120. Then, based on the number of write times, the connection unit 120 may execute a data process to determine the importance of data written into the first NM memory 132 or the correlation of the plurality of data sets written thereinto. Then, based on the number of write times, the connection unit 120 may execute a data process to determine the importance of the data written into the first NM memory 132 or the correlation of the plurality of data sets.

Moreover, the storage system 1 of the first embodiment may execute back up of data stored in the first NM memory 132 based on the importance of the data. Furthermore, the storage system 1 according to the first embodiment may carry out the back up by duplicating the data of which importance is equal to or greater than the criteria and writing into a region of the storage system 1 which is physically distant from the original region, to improve the reliability of the storage system 1.

Furthermore, the storage system 1 according to the first embodiment may cause key information sets (information sets) for the plurality of data sets of which correlation is determined to be equal to or greater than the criteria to be the same, in order to improve the speed of accessing the plurality of data sets. Moreover, the storage system 1 according to the first embodiment may cause access of the plurality data sets of which correlation is equal to or greater than the criteria to be distributed, in order to improve the speed of accessing the plurality of data sets.

### Second Embodiment

A second embodiment is described below. The storage system according to the second embodiment is different from the storage system 1 according to the first embodiment in that the counter 1312 of the memory unit MU counts the number of write times for each of a plurality of storage regions of the non-volatile memory. The storage region is a unit of data writing. The transmitter of the memory unit MU transmits, to the write controller (the connection unit 120), the number of write times counted by the counter 1312. Below, this difference will be mainly described.

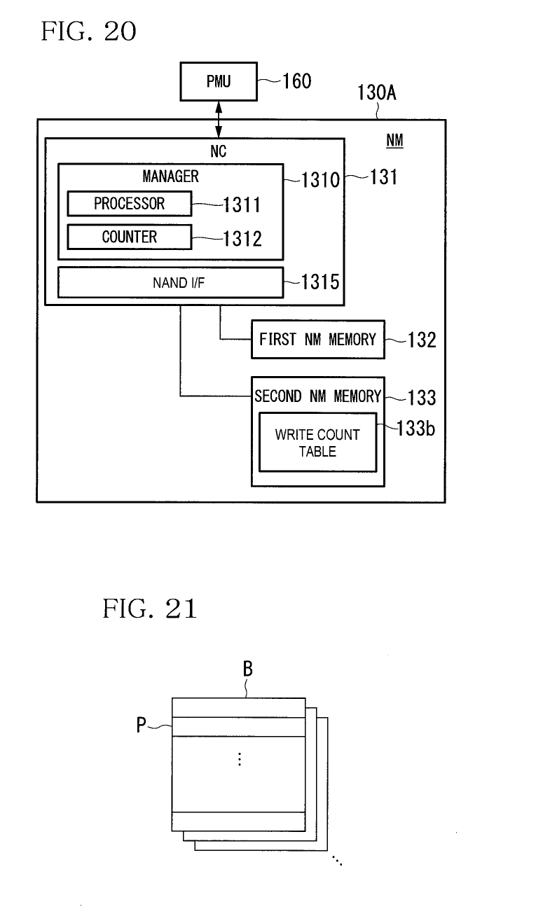

FIG. 20 illustrates a configuration of a node module 130A according to the second embodiment. The NAND interface 1315 in the node controller 131 writes data into each region (P), which is the write unit, of a plurality of blocks (B) included in the first NM memory 132. FIG. 21 illustrates a relationship between block and the write unit. The block is a data erase unit in the first NM memory 132, for example. A data writing unit is called a cluster of which size is smaller than that of the block and is, for example, equal to the size of a page of the NAND memory.

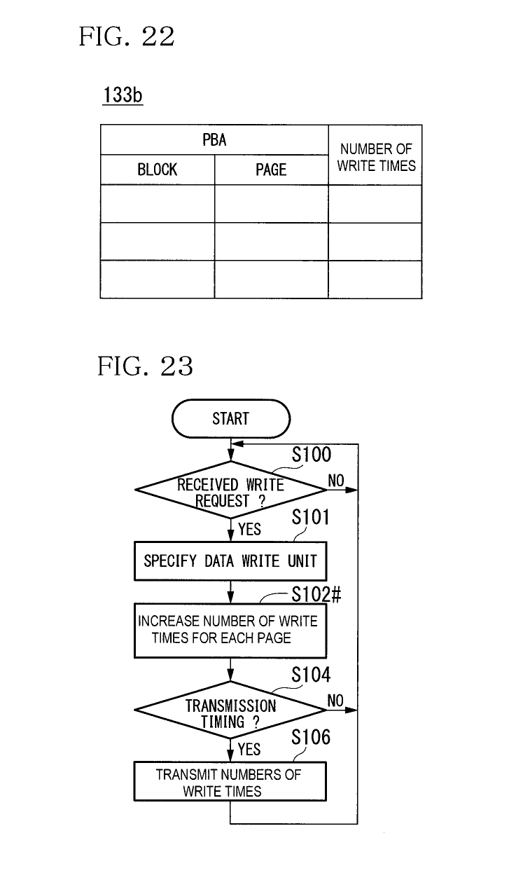

The node controller 131 stores, in the second NM memory 133, a write count table 133b in which each physical address and the number of write times therein are associated. FIG. 22 illustrates a structure of the write count table 133b according to the second embodiment. The write count table 133b includes the number of write times in association with a physical block address and a physical page address of the first NM memory 132. If the data are written into a page of a block of the first NM memory 132 based on a write request, the number of write times corresponding to the page of the block in the write count table 133b is updated.

FIG. 23 is a flow chart illustrating an operation of the node module 130 in the storage system 1 according to the second embodiment. The node controller 131 determines whether or not a write command has been received (S100). If a write request is not received (No in S100), the node controller 131 stay on standby. If a write request is received (Yes in S100), the node controller 131, based on a physical address included in the write command, specifies a target block(s) and a target page(s) thereof of the first NM memory 132 (S101). The counter 1312 of the node controller 131 updates the write count table 133b by increasing the number of write times to the specified page of the specified block (S102#).

The processor 1311 determines whether or not the timing to transmit the number of write times to the connection unit 120 has arrived (S104). If a repeat period to transmit the number of write times is determined to have arrived, the processor 1311 determines that the transmission timing has arrived. Alternatively, when the number of write times exceeds a predetermined threshold value, the processor 1311 may determine that the transmission timing has arrived. If the transmission timing has not arrived (No in S104), the process returns to S100. If the transmission timing has arrived (Yes in S104), information in the write count table 133b is read to the NAND interface 1315 and then transmitted to the connection unit 120 (S106).

As described above, the storage system 1 of the second embodiment counts the number of write times for each region of the first NM memory 132, which is a data writing unit, so that the storage system 1 can determine the importance, correlation, etc., of data based on the number of write times stored in each region.

### Third Embodiment

A third embodiment is described below. The third embodiment is different from the second embodiment in that the write controller (the connection unit 120) determines the number of write times metadata have been written into the non-volatile memory, which is received from the transmitter of the memory unit MU, and the processor 121 performs a data processing for data associated with the metadata based on the received number of write times. Below, this difference will be mainly described.

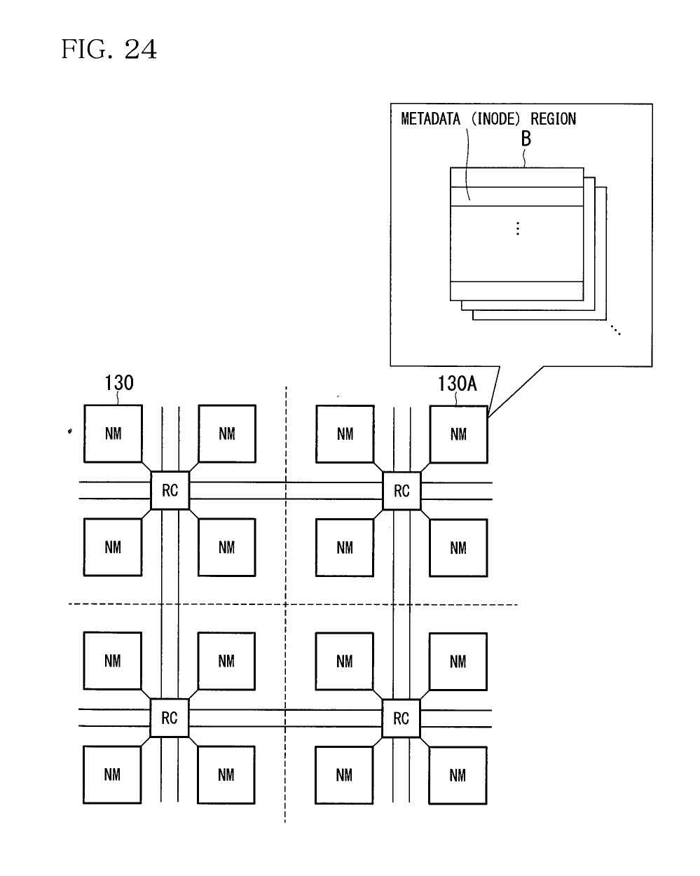

FIG. 24 schematically illustrates a region of the node module in which metadata are stored according to the third embodiment. An arbitrary node module 130A of the plurality of node modules 130 is set as a region (a memory unit MU, physical address (block or page)) in which the metadata are stored. That is, for the region in which the metadata are stored, a block (B) and a page (P) therein of the first NM memory 132 are specified. The metadata refer to additional information on data stored in the node module 130. In the present embodiment, the metadata are, for example, inode information. The inode information includes information such as a file name, the storage position of the file, access authorization, etc., for example.

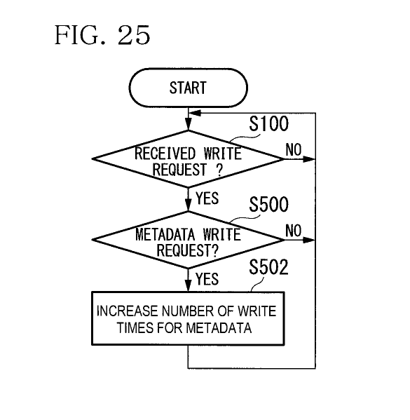

FIG. 25 is a flow chart illustrating a process of writing metadata in the storage system 1 according to the third embodiment. The node controller 131 determines whether or not a write request has been received (S100). If a write request is not received (No in S100), the node controller 131 stays on standby. If a write request is received (Yes in S100), the node controller 131, based on the write request, executes a write process of data instructed by the write request on the physical address (memory unit MU, block and page) designated by the write request. When the data instructed to be written based on the write request is metadata (Yes in S500), the node controller 131 increases the number of write times for the metadata in the write count table 133b (S502). While the node controller 131 does not recognize that the data written in accordance with the write request are metadata, the connection unit 120 recognizes the physical address into which the data are written.

The connection unit 120 receives information registered in the write count table 133b and performs a data process on data for which the metadata is generated, based on the number of write times for the metadata in the write count table 133b. In other words, the connection unit 120 determines, on the data corresponding to the metadata, as to whether the importance of the data is equal to or greater than the criteria, or determines whether the correlation of the plurality of data sets are equal to or greater than the criteria.

As described above, the storage system 1 according to the third embodiment counts the number of write times for metadata written into the first NM memory 132 and performs the data process of data for which the metadata is generated. Moreover, the storage system 1 according to the third embodiment can determine the importance of a file stored and the correlation of the files by counting the number of write times for data indicating attributes of a file, such as inode information.

### Fourth Embodiment

A fourth embodiment is described below. The fourth embodiment is different from the second embodiment in that the write controller (the connection unit 120) determines the number of write times lock information has been written into a non-volatile memory of a memory unit MU, which is received from a transmitter of the memory unit MU, based on an address in which the lock information has been written, and that the processor 121 performs a data processing for data associated with the lock information based on the received number of write times. Below, this difference will be mainly described.

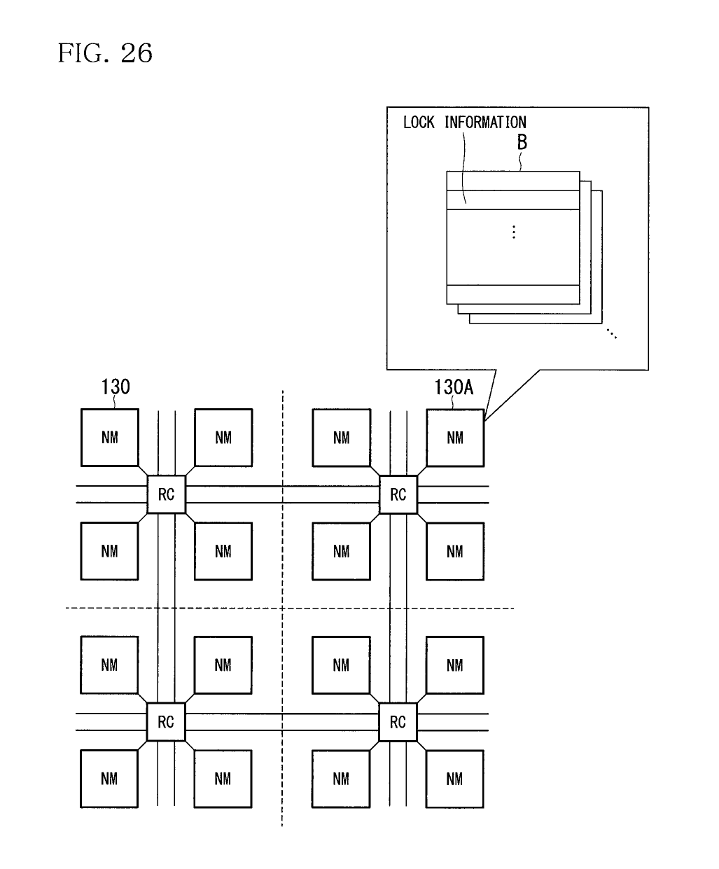

FIG. 26 schematically illustrates a region of the storage system 1 in which lock information is stored in the node module according to the fourth embodiment. A region in an arbitrary node module 130A is set as a region to store lock information included in a table in a relational database. For a region to store the lock information, a block (B) and a page (P) therein of the first NM memory 132 are specified. The lock information is information used to lock (prohibit) update of information registered in the relational database and is updated in response to releasing or setting of the lock by the connection unit 120. When the data in the relational database is going to be updated, the connection unit 120 refers to the lock information corresponding to the data to determine whether the update of the data is permitted or prohibited. If it is determined that update of the data in the relational database is prohibited, the connection unit 120 does not carry out the process of updating the data. If it is determined that the update of the data in the relational database is permitted, the connection unit 120 carries out a process of updating the data.

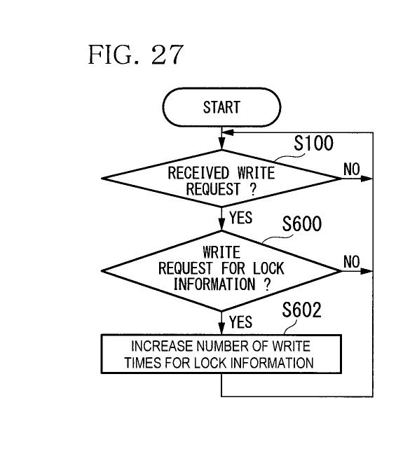

FIG. 27 is a flow chart illustrating a process of writing the lock information in the storage system 1 according to the fourth embodiment. The node controller 131 determines whether or not a write request has been received (S100). If a write request is not received (No in S100), the node controller 131 stays on standby. If the write request is received (Yes in S100), the node controller 131, based on the write request, executes a write process of data instructed by the write request to a physical address (block and page) instructed by the write request. When the write request further instructs to write lock information (Yes in S600), the node controller 131 writes the lock information to the block and page instructed by the write request and increase the number of write times corresponding to the lock information in the write count table 133b (S602). While the node controller 131 does not recognize that data written in accordance with the write request is lock information, the connection unit 120 recognizes the physical address into which the lock information is written.

The connection unit 120 receives information registered in the write count table 133b and performs a data process of a table to manage the lock information based on the number of write times corresponding to the lock information in the write count table 133b.

As described above, the storage system 1 according to the fourth embodiment counts the number of write times for the lock information to determine the importance and the correlation of the tables that are stored in the storage system 1.

### [Variation]

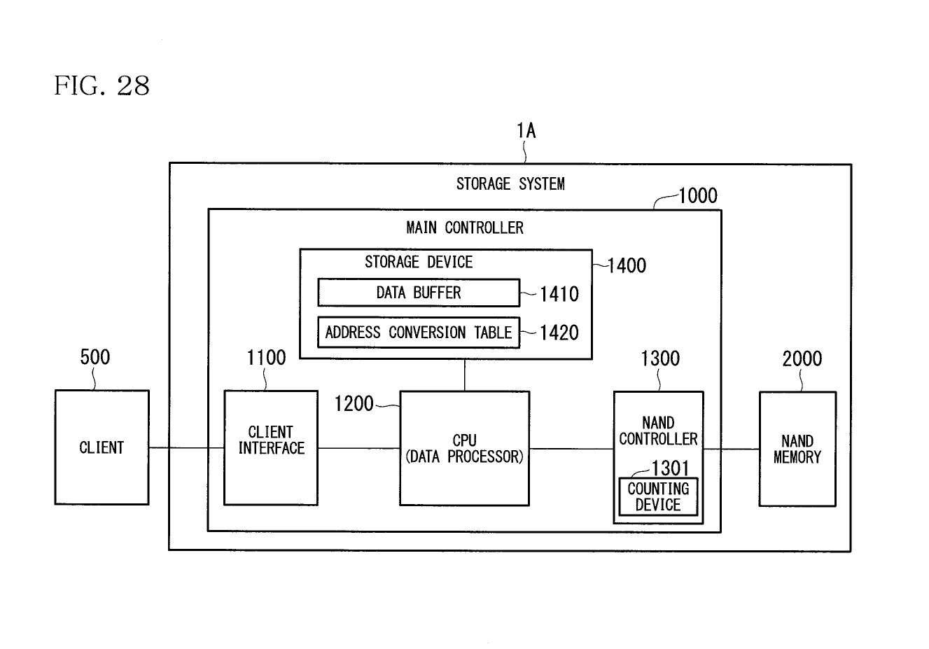

Below variations of the embodiments are described. FIG. 28 illustrates a configuration of a storage system 1A according to a first variation. The storage system 1A according to the first variation is a solid state drive (SSD). While the storage system 1A includes a main controller 1000 and a NAND flash memory (NAND memory) 2000, the configuration of the storage system 1A is not limited thereto. While the main controller 1000 includes a client interface 1100, a CPU 1200, a NAND controller (NANDC) 1300, and a storage device 1400, the configuration of the main controller 1000 is not limited thereto. The client interface 1100, for example, includes an SATA (serial advanced technology attachment) interface, an SAS (serial attached SCSI (small computer system interface)) interface, etc. The client 500 reads data written into the storage system 1A, or writes data into the storage system 1A. The NAND memory 2000 includes a non-volatile semiconductor memory and stores user data required by a write command transmitted by the client 500.

The storage device 1400 includes a semiconductor memory which can be accessed at a speed higher than the NAND memory 200 and randomly. While the storage device 1400 may be an SDRAM (synchronous dynamic random access memory) or an SRAM (static random access memory), the configuration of the storage device 1400 is not limited thereto. While the storage device 1400 may include a storage region used as a data buffer 1410 and a storage region in which an address conversion table 1420 is stored, the configuration of the storage device 1400 is not limited thereto. The data buffer 1410 temporarily stores data included in a write command, data read based on a read command, data re-written into the NAND memory 2000, etc. The address conversion table 1420 indicates a relationship between key information and a physical address.

The CPU 1200 executes programs stored in a program memory. The CPU 1200 executes processes such as read-write control on data based on a command transmitted by the client 500, garbage collection on the NAND memory 200, refresh write, etc. The CPU 1200 outputs a read command, a write command, or an erase command to the NAND controller 1300 to carry out read, write, or erasure of data.

While the NAND controller 1300 may include a NAND interface circuit which performs a process of interfacing with the NAND memory 2000, an error correction circuit, a DMA controller, etc., the configuration of the NAND controller 1300 is not limited thereto. The NAND controller 1300 writes data temporarily stored in the storage device 1400 into the NAND memory 2000 and read the data stored in the NAND memory 2000 to transfer the read result to the storage device 1400.

The NAND controller 1300 includes a counter 1312. The counter 1312 counts the number of times data are written into the NAND memory 2000 for each block or for each page. The counter 1312 increments the number of write times for each block or for each page each time a write request is output to the NAND memory 2000 based on the block and page which indicate a physical address included in a write command received from the CPU 1200. The number of write times counted by the counter 1312 is transmitted to the CPU 1200.

A storage system 1A according to the first variation may determine, by the CPU (processor) 1200, the importance or correlation of data based on the number of write times for each block or each page that is counted by the NAND controller 1300.

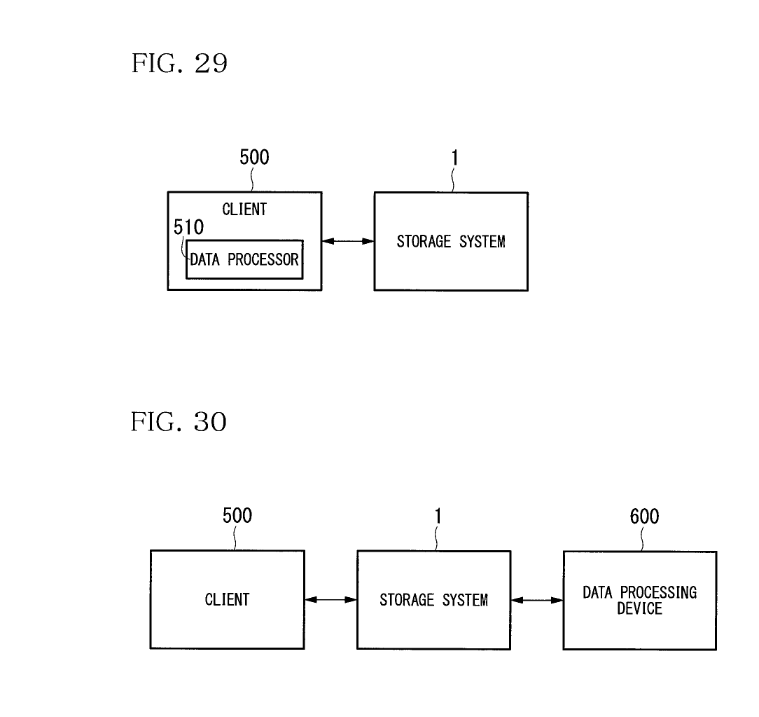

FIG. 29 illustrates a second variation. According to the second variation, the client 500 includes a data processor 510. The importance or correlation of data based on the number of write times for each page, for each block, or for the first NM memory 132 that is counted by the storage system 1 is transmitted to the data processor 510. The data processor (processor) 510 performs various processes such as instructions for backup of data based on the importance or correlation of the data.

FIG. 30 illustrates a third variation. According to the third variation, a data processing device 600 is connected to the storage system 1. The importance or correlation of data based on the number of write times for each page, for each block, or for the first NM memory 132 that is counted by the storage system 1 is transmitted to the data processing device 600. The data processing device or (processor) 600 performs various processes such as instructions for backup of data based on the importance or correlation of the data.

At least one embodiment as described above may include a write controller 120 which specifies a memory unit 130 including a non-volatile memory 132 based on information included in a write command transmitted by an external device 500; a non-volatile memory 132, a writer 131 which writes data into the non-volatile memory 132 based on a write request received from the write controller 120, and a counter 1312 which counts the number of times in which data are written by the write device 131 to output the counted result to the write controller 120 to detect the importance, the correlation, etc., of data based on the number of times included in the memory unit 130.

While certain embodiments have been described, these embodiments have been presented by way of example only, and are not intended to limit the scope of the inventions. Indeed, the novel embodiments described herein may be embodied in a variety of other forms: furthermore various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A storage device, comprising:
a storage unit having a plurality of routing circuits electrically networked with each other, each of the routing circuits being locally connected to a plurality of node modules, each of the node modules including a nonvolatile memory device and is configured to count a number of times write operations have been carried out with respect thereto and output the counted number of times; and
a plurality of connection units, each connected to one or more of the routing circuits, and configured to access each of the node modules through one or more of the routing circuits, in accordance with access requests from a client, wherein
each of the connection units maintains, in each entry of a table, a key address of data written thereby and attributes of the data, the attributes including the number of times corresponding to a nonvolatile memory device into which the data have been written.

2. The storage device according to claim 1, wherein
when the number of times maintained by a connection unit in association with data stored in a first node module reaches a predetermined value, said connection unit operates to back up the data stored in the first node module into a second node module that is different from the first node module.

3. The storage device according to claim 2, wherein
the second node module is locally connected to a second routing circuit different from a routing circuit that is locally connected to the first node module.

4. The storage device according to claim 2, wherein
the storage unit is formed of a plurality of circuit boards, in each of which one or more connection units and the plurality of node modules locally connected thereto are mounted, and
the second node module is mounted on a second circuit board that is different from a first circuit board on which the first node module is mounted.

5. The storage device according to claim 1, wherein
when a difference between the number of times maintained in a first entry of the table in a first connection unit and the number of times maintained in a second entry of the table in the first connection unit is smaller than a predetermined value, the first connection unit updates the table, such that first data corresponding to the first entry and second data corresponding to the second entry are associated with a same key address.

6. The storage device according to claim 5, wherein
when the first connection unit receives an access request including said same key address, the first connection unit access both the first data and the second data.

7. The storage device according to claim 5, wherein
when the first data and the second data are stored in a same node module or different node modules locally connected to a same routing circuit, the first connection unit operates to transfer at least one of the first and second data to a node module connected to a different routing circuit.

8. The storage device according to claim 1, wherein
a first entry of a table maintained by a connection unit is associated with user data stored in a first node module, and a second entry of the table maintained by the connection unit is associated with metadata thereof that is stored in a second node module, and
when the number of times maintained in the first entry reaches a predetermined value, the connection unit operates to back up the user data into a third node module.

9. The storage device according to claim 1, wherein
an entry of a table maintained by a connection unit is associated with data indicating whether or not update of the table is allowed,
when the number of times maintained in the first entry reaches a predetermined value, the connection unit operates to back up data associated with another entry of the table.

10. A storage device, comprising:
a storage unit having a plurality of routing circuits electrically networked with each other, each of the routing circuits being locally connected to a plurality of node modules, each of the node modules including a nonvolatile memory device including a plurality of pages and is configured to count a number of times write operations have been carried out with respect each of the pages and output the counted numbers of times; and
a plurality of connection units, each connected to one or more of the routing circuits, and configured to access each of the node modules through one or more of the routing circuits, in accordance with access requests from a client, wherein
each of the connection units maintains, in each entry of a table, a page address of a page and the number of times corresponding to the page.

11. The storage device according to claim 10, wherein
when the number of times maintained by a connection unit in association with data stored in a page of a first node module reaches a predetermined value, said connection unit operates to back up the data stored in the page into a page of a second node module that is different from the first node module.

12. The storage device according to claim 11, wherein
the second node module is locally connected to a second routing circuit different from a routing circuit that is locally connected to the first node module.

13. The storage device according to claim 11, wherein
the storage unit is formed of a plurality of circuit boards, in each of which one or more connection units and the plurality of node modules locally connected thereto are mounted, and
the second node module is mounted on a second circuit board that is different from a first circuit board on which the first node module is mounted.

14. The storage device according to claim 10, wherein
when a difference between the number of times maintained in a table of a connection unit in association with first data stored in a first page and the number of times maintained in the table in association with second data stored in a second page is smaller than a predetermined value, the first connection unit updates the table, such that the first data and the second data are associated with a same key address.

15. The storage device according to claim 14, wherein
when said connection unit receives an access request including said same key address, said connection unit access both the first data and the second data.

16. The storage device according to claim 14, wherein
when the first data and the second data are stored in a same node module or different node modules locally connected to a same routing circuit, the first connection unit operates to transfer at least one of the first and second data to a node module connected to a different routing circuit.

17. The storage device according to claim 10, wherein
a first entry of a table maintained by a connection unit is associated with user data stored in a page of a first node module, and a second entry of the table maintained by the connection unit is associated with metadata thereof that is stored in a page of a second node module, and
when the number of times maintained in the first entry reaches a predetermined value, the connection unit operates to back up the user data into a page of a third node module.

18. The storage device according to claim 10, wherein
an entry of a table maintained by a connection unit is associated with data indicating whether or not update of the table is allowed,
when the number of times maintained in the first entry reaches a predetermined value, the connection unit operates to back up data associated with another entry of the table.
